(19) United States
(12) Patent Application Publication
(10) Pub. No.: US 2009/0273044 A1
(43) Pub. Date: Nov. 5, 2009

(54) Semiconductor Device, Memory Module, and Method of Manufacturing a Semiconductor Device

(76) Inventor: Rainer Leuschner, Regensburg (DE)

Correspondence Address: SLATER & MATSIL, L.L.P., 17950 PRESTON ROAD, SUITE 1000, DALLAS, TX, 75252, US

(21) Appl. No.: 12/115,248

(22) Filed: May 5, 2008

(51) Int. Cl. H01L 29/82; H01L 21/00

(52) U.S. Cl. 257/421; 438/3; 257/E29.323; 257/E21.001

(57) ABSTRACT

According to one embodiment of the present invention, a semiconductor device is provided including a semiconductor chip. The semiconductor chip is at least partly surrounded by a surrounding structure. The semiconductor chip further includes a magneto-resistive memory cell. A shielding layer is disposed between the semiconductor chip and the surrounding structure, wherein the shielding layer is configured to shield the magneto-resistive memory cell from external magnetic fields.

### BACKGROUND

Semiconductor devices including magneto-resistive memory cells are known. An example of a part of such a semiconductor device is shown in FIG. 1.

FIG. 1 illustrates a perspective view of a part of a MRAM chip 100 having bit lines 112 located orthogonal to word lines 114 in adjacent metallization layers. Magnetic stacks 116 are positioned between the bit lines 112 and word lines 114 adjacent and electrically coupled to bit lines 112 and word lines 114. Magnetic stacks 116 preferably include multiple layers, including a soft layer 118, a tunnel layer 120, and a hard layer 122, for example. Soft layer 118 and hard layer 122 preferably include a plurality of magnetic metal layers, for example, eight to twelve layers of materials such as PtMn, CoFe, Ru, and NiFe, as examples. A logic state is storable in the soft layer 118 of the magnetic stacks 116 located at the junction of the bit lines 112 and word lines 114 by running a current in the appropriate direction within the bit lines 112 and word lines 114 which changes the resistance of the magnetic stacks 116.

In order to read the logic state stored in the soft layer 118 of a selected magnetic stack 116, a schematic such as the one shown in FIG. 2, including a sense amplifier (SA) 230, is used. A reference voltage U_{R} is applied to one end of the selected magnetic stack 116. The other end of the selected magnetic stack 116 is coupled to a measurement resistor Rₘ₁. The other end of the measurement resistor Rₘ₁ is coupled to ground. The current running through the selected magnetic stack 116 is equal to current I_{cell}. A reference circuit 232 supplies a reference current I_{ref} that is run into measurement resistor Rₘ₂. The other end of the measurement resistor Rₘ₂ is coupled to ground, as shown.

It is desirable to improve the reliability of semiconductor devices as described above during operation.

### SUMMARY OF THE INVENTION

According to one embodiment of the present invention, a semiconductor device is provided including a semiconductor chip. The semiconductor chip is at least partly surrounded by a surrounding structure. The semiconductor chip further includes a magneto-resistive memory cell. A shielding layer is disposed between the semiconductor chip and the surrounding structure, wherein the shielding layer is configured to shield the magneto-resistive memory cell from external magnetic fields.

According to one embodiment of the present invention, a method of manufacturing a semiconductor device including a semiconductor chip and a magneto-resistive memory cell arranged within the semiconductor chip is provided, the method including: forming a composite structure including the semiconductor chip and a shielding layer which at least partly surrounds the semiconductor chip, wherein the shielding layer protects the magneto-resistive memory cell against an external magnetic field, and at least partly surrounding the composite structure with a surrounding structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic perspective view of a part of a semiconductor chip;

FIG. 2 shows an integrated circuit useable in conjunction with the memory device shown in FIG. 1;

FIG. 3 shows a schematic cross-sectional view of a semiconductor device according to one embodiment of the present invention;

FIG. 4 shows a flow chart of a method of manufacturing a semiconductor device according to one embodiment of the present invention;

FIG. 5A shows a processing stage of a method of manufacturing a semiconductor device according to one embodiment of the present invention;

FIG. 5B shows a processing stage of a method of manufacturing a semiconductor device according to one embodiment of the present invention;

FIG. 5C shows a processing stage of a method of manufacturing a semiconductor device according to one embodiment of the present invention;

FIG. 5D shows a processing stage of a method of manufacturing a semiconductor device according to one embodiment of the present invention;

FIG. 5E shows a processing stage of a method of manufacturing a semiconductor device according to one embodiment of the present invention;

FIG. 5F shows a processing stage of a method of manufacturing a semiconductor device according to one embodiment of the present invention;

FIG. 5G shows a processing stage of a method of manufacturing a semiconductor device according to one embodiment of the present invention;

FIG. 5H shows a processing stage of a method of manufacturing a semiconductor device according to one embodiment of the present invention;

FIG. 6 shows schematic cross-sectional view of a semiconductor device according to one embodiment of the present invention;

FIG. 7A shows a schematic perspective view of a memory module according to one embodiment of the present invention; and

FIG. 7B shows a schematic perspective view of a memory module according to one embodiment of the present invention.

### DETAILED DESCRIPTION OF ILLUSTRATIVE EMBODIMENTS

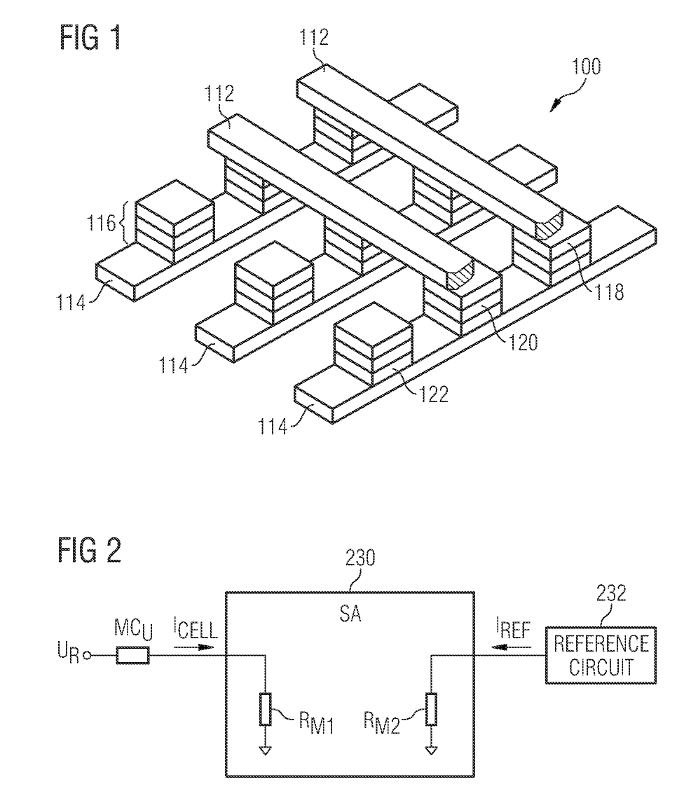

The memory chip as shown in FIG. 1 may be used as part of a semiconductor device according to one embodiment of the present invention.

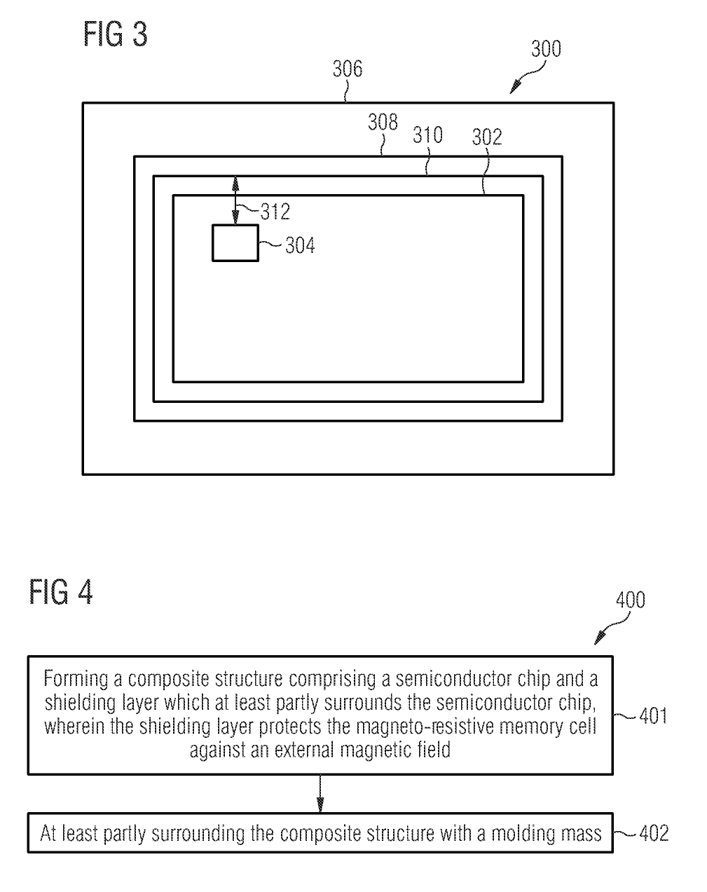

FIG. 3 shows a semiconductor device 300 according to one embodiment of the present invention. The semiconductor device 300 includes a semiconductor chip 302 (which may, for example, be the semiconductor chip 100 shown in FIG. 1) which includes at least one magneto-resistive memory cell 304. The semiconductor chip 302 is as least partly surrounded by a surrounding structure 306, e.g., a molding mass. Between the semiconductor chip 302 and the surrounding structure 306, a shielding layer 308 is arranged which shields the magneto-resistive memory cell 304 against external magnetic fields.

According to one embodiment of the present invention, the surrounding structure 306 is a molding mass. However, the embodiments of the present invention are not restricted thereto; the surrounding structure 306 may include arbitrary kinds of packaging elements made of arbitrary materials. For example, the surrounding structure may include a combination of a molding mass and further packaging elements.

According to one embodiment of the present invention, the semiconductor chip 302 includes an integrated circuit including a plurality of magneto-resistive memory cells, for example, a magneto-resistive memory device. A part of the semiconductor chip 302 may, for example, be designed like the semiconductor chip 100 shown in FIG. 1.

According to one embodiment of the present invention, the thickness of the shielding layer 308 ranges from about 10 μm to about 100 μm. Good results have been shown using a range from about 20 μm to about 50 μm.

According to one embodiment of the present invention, the shielding layer 308 includes or consists of metallic material, for example, NiFeCo alloys, and the like. Good results have been shown using NiFe (permalloy).

According to one embodiment of the present invention, between the shielding layer 308 and the semiconductor chip 302, an isolation layer 310 may be arranged.

According to one embodiment of the present invention, the isolation layer 310 includes a first isolation layer and a second isolation layer arranged on or above the first isolation layer, wherein the material of the first isolation layer is different from the material of the second isolation layer. For example, the first isolation layer may include or consist of SiO₂, and the second isolation layer may include or consist of SiN.

According to one embodiment of the present invention, a distance 312 between the shielding layer 308 and (one of) the magneto-resistive memory cell(s) 304 ranges from about 2 μm to about 40 μm. Good results have been shown using a distance range from about 15 μm to about 25 μm.

According to one embodiment of the present invention, a memory module including at least one semiconductor device 300 including a semiconductor chip 302 including at least one magneto-resistive memory cell 304 is provided. The semiconductor chip 302 is at least partly surrounded by a surrounding structure 306. Between the semiconductor chip 302 and the surrounding structure 306, a shielding layer 308 is arranged which shields the magneto-resistive memory cell 304 against external magnetic fields.

According to one embodiment of the present invention, the memory module is stackable.

FIG. 4 shows a method 400 of manufacturing a semiconductor device according to one embodiment of the present invention. At 401, a composite structure including a semiconductor chip and a shielding layer which at least partly surrounds the semiconductor chip is formed, wherein the shielding layer protects the magneto-resistive memory cell against an external magnetic field. At 402, the composite structure is at least partly surrounded with a surrounding structure, e.g., a molding mass.

One effect of surrounding the semiconductor chip with a shielding layer before covering the shielding layer with the surrounding structure is that, in contrast to known solutions, the shielding layer is positioned close to the semiconductor chip (in known solutions, there is a large distance between the shielding layer and the semiconductor chip since the shielding layer is not located between the surrounding structure and the semiconductor chip, but covers the surrounding structure; however, the large distance between the semiconductor chip and the shielding layer leads to rather strong shielding layer thicknesses, compared to the embodiments of the present invention where, due to a reduced distance between a shielding layer and the semiconductor chip, lower shielding layer thicknesses are sufficient).

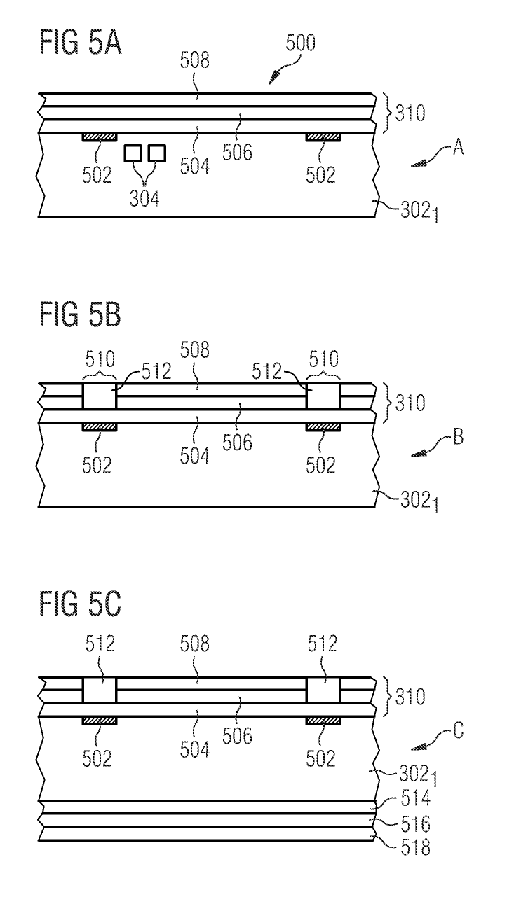

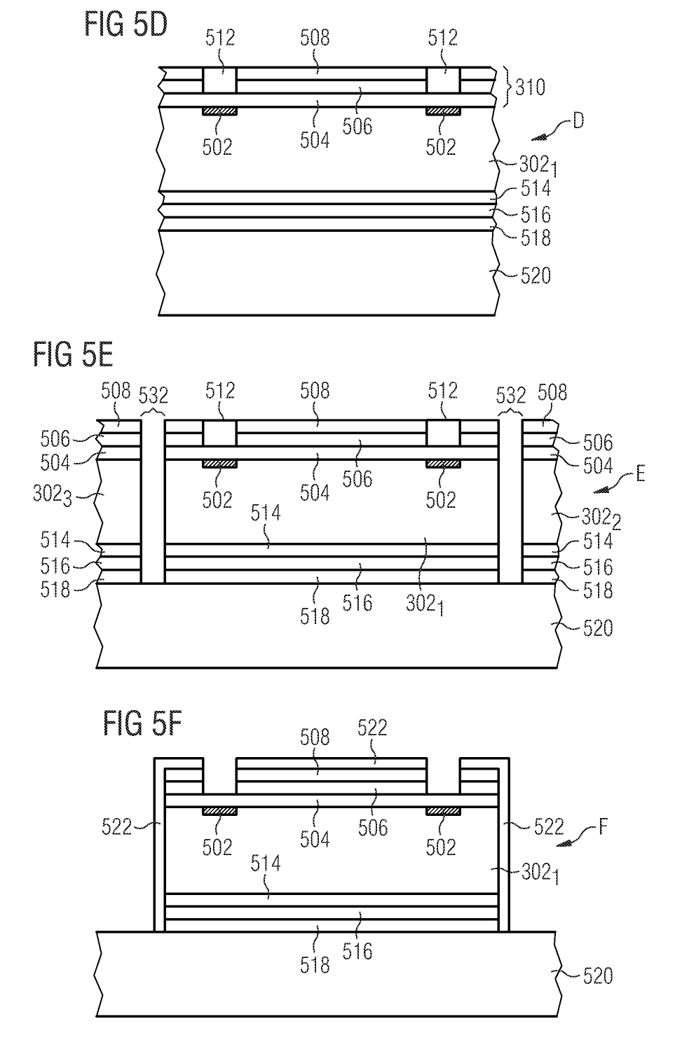

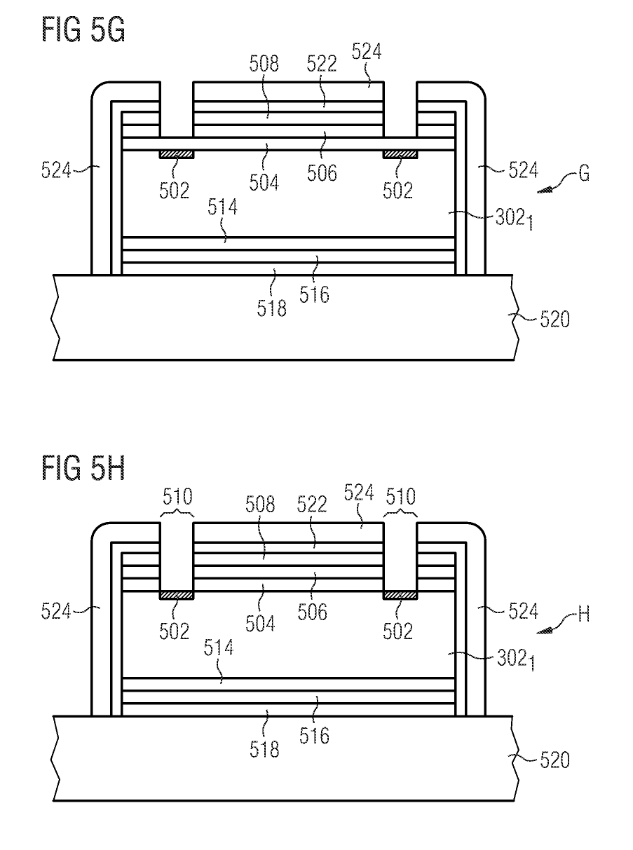

In the following description, making reference to FIGS. 5A to 5H, a method 500 of manufacturing a semiconductor device according to one embodiment of the present invention will be explained.

In a processing stage A shown in FIG. 5A, a semiconductor chip layer 302 has been provided. Within the semiconductor chip layer 302, a plurality of semiconductor chips (for sake of simplicity, only a part of the semiconductor chip layer 302, i.e., one semiconductor chip 302₁, is shown), e.g., a plurality of magneto-resistive memory chips, has been formed. It is assumed here that the semiconductor chip layer 302 is a semiconductor wafer. The semiconductor chip 302₁ includes semiconductor chip contacting areas 502. The semiconductor chip layer 302 has been covered with a first isolation layer 504, a second isolation layer 506 arranged on the first isolation layer 504, and a third isolation layer 508 arranged on the second isolation layer 506.

According to one embodiment of the present invention, the first isolation layer 504 includes or consists of SiO₂. According to one embodiment of the present invention, the second isolation layer 506 includes or consists of SiN. According to one embodiment of the present invention, the third isolation layer 508 includes or consists of dielectric material, for example, polyimide.

According to one embodiment of the present invention, the thickness of the first isolation layer 504 ranges between about 50 nm and about 1000 nm. Good results have been shown using a thickness of about 100 nm. According to one embodiment of the present invention, the thickness of the second isolation layer 506 ranges between about 20 nm and about 500 nm. Good results have been shown using a thickness of about 50 nm. According to one embodiment of the present invention, the third isolation layer 508 has a thickness of about 1 μm to about 30 μm. Good results have been shown using a thickness of about 10 μm to about 20 μm.

According to one embodiment of the present invention, the third isolation layer 508 comprises or consists of a dielectric material like polyimide. According to one embodiment of the present invention, the third isolation layer 508 comprises or consists of a material which can be structured using light. For example, a photo patternable polyimide or a photo patternable epoxy resist may be used. According to one embodiment of the present invention, the third isolation layer 508 comprises or consists of low-k material.

According to one embodiment of the present invention, the third isolation layer 508 is used for defining the contact holes 510 (FIG. 5B), i.e., the patterned third isolation layer 508 is used as a mask for patterning the second isolation layer 506.

According to one embodiment of the present invention, the semiconductor chip contacting areas 502 are, for example, conductive pads like aluminum pads which are electrically connected to magneto-resistive memory cells 304 embedded into the semiconductor chip 302.

FIG. 5B shows a processing stage B in which contact holes 510 have been formed within the second isolation layer 506 and the third isolation layer 508 and have been filed with filling material 512 (for example, photo resist material). Here, the bottom surface of the contact holes 510 coincides with the top surface of the first isolation layer 504. In order to form the contact holes 510, for example, a selective etching process may be used; in this case, it is advantageous if the first isolation layer 504 and the second isolation layer 506 consist of different materials in order to use the first isolation layer 504 as an etching stop layer.

Then, as indicated by processing stage C shown in FIG. 5C, a seed layer 514 is provided on the back side of the semiconductor chip 302₁. After this, a shielding layer 516 is formed on the seed layer 514. Then, an adhesive layer 518 is formed on the shielding layer 516.

Then, as shown in processing stage D in FIG. 5D, the adhesive layer 518 is used in order to fix the semiconductor chip 302₁ on a supporting element layer 520, for example, a supporting wafer.

According to one embodiment of the present invention, the seed layer 514 has a thickness ranging form about 10 nm to about 100 nm. According to one embodiment of the present invention, the shielding layer 516 has a thickness ranging between about 10 μm and about 100 μm. According to one embodiment of the present invention, the shielding layer 516 has a thickness ranging form about 20 μm to about 50 μm. According to one embodiment of the present invention, the seed layer 514 and the shielding layer 516 include or consist of the same material, for example, NiFe. Another example of possible seed layer material is copper (Cu). According to one embodiment of the present invention, before forming the shielding layer 516 on the seed layer 514, a pre-cleaning of the surface of the seed layer 514 may be carried out. The seed layer 514 may, for example, be formed using a sputter process or a vapor deposition process.

Then, as shown in processing stage E in FIG. 5E, the composite structure including the adhesive layer 518, the shielding layer 516, the seed layer 514, the semiconductor chip layer 302, the first isolation layer 504, the second isolation layer 506 and the third isolation layer 508 is patterned down at least into the adhesive layer 518. In this way, the composite structure is singularized into singular stacks of layers, i.e., into areas respectively including one stack of layers by forming trenches 532. For sake of simplification, only three singularized stacks of layers (including semiconductor chips 302₁ to 302₃, respectively) are shown in FIG. 5E. According to one embodiment of the present invention, the singularization process is carried out using a saw or a laser beam. According to one embodiment of the present invention, the adhesive layer 518 is a thermo release layer, i.e., the singularized stacks of layers can be removed from the supporting element layer 520 by annealing the adhesive layer 518.

In a processing stage F shown in FIG. 5F, a seed layer 522 has been formed on the surface of the composite structure which has been fixed on the supporting element layer 520. For sake of simplicity, in FIGS. 5F to 5H, only the semiconductor chip 302₁ is shown. Then, the parts of the seed layer 522 located over the filling material 512 as well as the filling material 512 are removed. The removal of the filling material 512 (“resist plugs”) may, for example, be carried out using an organic solvent together with a spray strip process or a lift-off process. Possible solvents are methoxy-propylacetat (MPA) or cyclopentaton or n-methylpyrrolidon (NMP). According to one embodiment of the present invention, the top surface of the filling material 512 is slightly higher than the top surface of the third isolation layer 508 and/or has slightly overhanging edges in order to enable an easier removal. Such properties of the filling material 512 can, for example, be obtained using special lift-off process photoresists.

In a processing stage G shown in FIG. 5G, a shielding layer 524 is formed on the seed layer 522 using, for example, an electro plating or a electroless plating process. As far as possible materials and thicknesses of the seed layer 522 and the shielding layer 524 are concerned, the same materials and thicknesses as discussed in conjunction with the seed layer 514 and the shielding layer 516 may be used.

According to one embodiment of the present invention, the third isolation layer 508 includes or consists of a material having a sufficient flexibility to compensate the coefficient of thermal expansion mismatch (“CTE mismatch”) between the semiconductor chip layer 302 and the shielding layer 524. For example, SiO₂ or Si nitride as materials for the third isolation layer 508 would not yield the required sufficient flexibility.

Optionally, a further layer having the same characteristics as the embodiments of the third isolation layer 508 described above may be formed between the seed layer 514 and the semiconductor chip layer 302.

In a processing stage H shown in FIG. 5H, the areas of the first isolation layer 504 located above the semiconductor chip contacting areas 502 are removed (using, for example, an etching process; if the first isolation layer 504 comprises or consists of SiO₂, for example, a buffered (e.g., buffered with NH₄F) HF solution (hydrofluoric acid) may be used in order to etch the first isolation layer 504); alternatively, a plasma process may be used in order to remove the areas of the first isolation layer 504 located above the semiconductor chip contacting areas 502). Then, the semiconductor chip contacting areas 502 can be contacted via the contact holes 510. After this, the whole structure shown in FIG. 5F can be embedded into molding mass (not shown). Before carrying out the molding mass embedding process, the supporting wafer 520 may be removed.

According to one embodiment of the present invention, the shielding layer 516, 524 has a thickness ranging from about 10 μm to about 100 μm, or a thickness ranging from about 20 μm to about 50 μm.

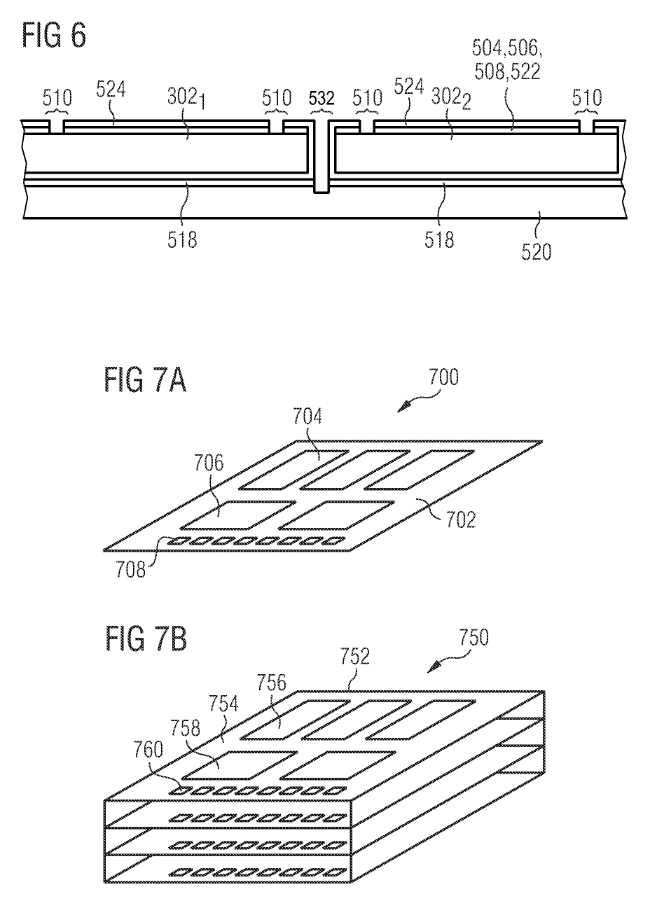

As shown in FIG. 6 (representing a further illustration of manufacturing stage H shown in FIG. 5H), a plurality of semiconductor chips 302 may be manufactured as described above in conjunction with FIGS. 5A to 5G using a common supportive wafer 520.

As shown in FIGS. 7A and 7B, in some embodiments, semiconductor devices such as those described herein may be used in modules. In FIG. 7A, a memory module 700 is shown, on which one or more semiconductor devices 704 are arranged on a substrate 702. The semiconductor device 704 includes numerous magneto-resistive memory cells. The memory module 700 may also include one or more electronic devices 706, which may include memory, processing circuitry, control circuitry, addressing circuitry, bus interconnection circuitry, or other circuitry or electronic devices that may be combined on a module with a memory device, such as the semiconductor device 704. Additionally, the memory module 700 includes multiple electrical connections 708, which may be used to connect the memory module 700 to other electronic components, including other modules.

As shown in FIG. 7B, in some embodiments, these modules may be stackable, to form a stack 750. For example, a stackable memory module 752 may contain one or more semiconductor devices 756, arranged on a stackable substrate 754. The semiconductor device 756 contains memory cells. The stackable memory module 752 may also include one or more electronic devices 758, which may include memory, processing circuitry, control circuitry, addressing circuitry, bus interconnection circuitry, or other circuitry or electronic devices that may be combined on a module with a memory device, such as the semiconductor device 756. Electrical connections 760 are used to connect the stackable memory module 752 with other modules in the stack 750, or with other electronic devices. Other modules in the stack 750 may include additional stackable memory modules, similar to the stackable memory module 752 described above, or other types of stackable modules, such as stackable processing modules, control modules, communication modules, or other modules containing electronic components.

In the following description, further aspects of embodiments of the present invention will be explained.

According to one embodiment of the present invention, a solution for compact magnetic shielding of MRAM chips with an overall small volume is provided. Shielding by a metallic cage is effective, but a relatively large cage is needed, because simulations showed that the larger the distance of the shield to the MRAM storage layer is, the thicker the shield must be in order to be effective. Such a cage would add up to about 1 mm on each side. In order to supply such a shield, a metal package may be provided into which the chip is placed. The size of the metal cage increases the overall chip size significantly, which has consequences for a tight mounting of MRAM chips in especially mobile applications.

According to one embodiment of the present invention, a magnetic shielding layer is deposited directly onto the chips in a wafer level process flow.

One effect of embodiments of the present invention is that a tight and cost effective packaging with magnetic shielding is provided. A process flow is provided that allows a much smaller packaged chip and is cost effective because it allows building the shield by electroless plating before the chips are separated from each other.

According to one embodiment of the present invention, a MRAM wafer in the final passivation gets covered with a polyimide or another comparable flexible dielectric layer (referred to as polyimide for simplicity). Then, the pads for bonding (which are covered with a SiO₂/SiN layer that is below the dielectric polymer) are opened by a reactive ion etching step. In the normal flow the chip will be diced out, bonded to a grid and molded with a flexible polymer. On top of that then comes a metallic cage with openings for the contacts of the grid is formed. Since the metallic cage is relatively far away from the magnetically sensitive storage layer (which needs to be shielded against external fields), it needs to be relatively thick and large.

According to one embodiment of the present invention, the process flow will be changed as follows: After the deposition and curing of the polyimide, the pads are not opened immediately, but only the SiN layer is etched with a stop on the SiO₂ layer. Then, on top of the polyimide, a photoresist is patterned that covers the pads and eventually the sloped polyimide directly around the pads. After that, the wafer gets sputtered with a seed layer (e.g. about 10 nm to about 100 nm NiFe or Cu deposition with a pre-clean step) on the back side. After the seed layer deposition on the backside of the wafer, a magnetic NiFe (permalloy) layer (about 30 micrometer thick) is electroplated. After this, the wafer is glued to a supporting wafer, and a kerf in between the chips is cut out with a water-jet laser cutter beginning form the front side of the wafer and stopping after the backside NiFe film. After that, the front side of the wafer gets sputtered with the seed layer. The photoresist is then stripped with a solvent on a spray developer tool lifting off the seed layer on the parts that were covered by the photoresist. After that, the front-side of the water gets electroplated with about a 30 micrometer thick magnetic NiFe (permalloy) layer. In that way, the complete chip is covered by the NiFe layer, except the pads (that are still protected by the SiO₂ layer) and eventually their direct vicinity where no seed layer was. Then, the SiO₂ layer is etched by a buffered HF solution in order to open the pads. Now, the chips can be released from the supporting wafer by mechanical and/or chemical means. Each chip is now ready for bonding and final packaging with the polymeric mold. There is no need for a relatively thick metallic cage because the plated NiFe that is close to the MRAM storage layer acts as a shield.

According to one embodiment of the present invention, a semiconductor device is provided including a semiconductor chip. The semiconductor chip is at least partly surrounded by a surrounding structure. The semiconductor chip further includes a magneto-resistive memory cell. A shielding layer is disposed between the semiconductor chip and the surrounding structure, wherein the shielding layer is configured to shield the magneto-resistive memory cell from external magnetic fields.

According to one embodiment of the present invention, the thickness of the shielding layer ranges from about 10 μm to about 100 μm. According to one embodiment of the present invention, the thickness of the shielding layer ranges from about 20 μm to about 50 μm.

According to one embodiment of the present invention, the shielding layer includes or consists of metallic material.

According to one embodiment of the present invention, the shielding layer includes or consists of NiFe.

According to one embodiment of the present invention, between the shielding layer and the semiconductor chip, a first isolation layer and a second isolation layer are arranged, wherein the material of the first isolation layer is different from the material of the second isolation layer.

According to one embodiment of the present invention, the first isolation layer includes or consists of SiO₂.

According to one embodiment of the present invention, the second isolation layer includes or consists of SiN.

According to one embodiment of the present invention, the distance between the shielding layer and the magneto-resistive memory cell ranges from about 2 μm to about 40 μm. According to one embodiment of the present invention, a memory module including at least one semiconductor device is provided. Each semiconductor device includes a semiconductor chip. The semiconductor chip is at least partly surrounded by a surrounding structure. The semiconductor chip further includes a magneto-resistive memory cell. A shielding layer is disposed between the semiconductor chip and the surrounding structure, wherein the shielding layer is configured to shield the magneto-resistive memory cell from external magnetic fields.

According to one embodiment of the present invention, the memory module is stackable.

According to one embodiment of the present invention, the surrounding structure is a molding mass.

According to one embodiment of the present invention, a method for manufacturing a semiconductor chip and a magneto-resistive memory cell arranged within the semiconductor chip is provided, the method including: forming a composite structure comprising the semiconductor chip and a shielding layer which at least partly surrounds the semiconductor chip, wherein the shielding layer protects the magneto-resistive memory cell against an external magnetic field; and at least partly surrounding the composite structure with a surrounding structure.

According to one embodiment of the present invention, the semiconductor chip includes semiconductor chip contacting areas located at or near to a top surface of the semiconductor chip.

According to one embodiment of the present invention, contact holes are formed within an isolation layer arranged on or above the semiconductor chip contact areas, wherein the contact holes do not reach to top surfaces of the semiconductor chip contact areas; the shielding layer is formed on or above a top surface of the isolation layer; and the contact holes are enlarged until they reach the top surfaces of the semiconductor chip contacting areas.

According to one embodiment of the present invention, the semiconductor chip contacting areas are contacted via the contact holes before surrounding the composite structure with the molding mass.

According to one embodiment of the present invention, the isolation layer includes a first isolation layer which is provided on or above the top surface of the semiconductor chip, and a second isolation layer which is provided on or above the first isolation layer, wherein the material of the first isolation layer is different from the material of the second isolation layer.

According to one embodiment of the present invention, wherein, before forming the shielding layer, the contact holes are formed such that they reach to a top surface of the first isolation layer, wherein, after having formed the shielding layer, the contact holes are enlarged such that they reach to the top surfaces of the semiconductor chip contacting areas.

According to one embodiment of the present invention, the first isolation layer includes or consists of SiO₂.

According to one embodiment of the present invention, the second isolation layer includes or consists of SiN.

According to one embodiment of the present invention, a seed layer is formed on or above the top surface of the isolation layer, wherein the shielding layer is formed on a top surface of the seed layer.

According to one embodiment of the present invention, the seed layer includes or consists of NiFe or Cu.

According to one embodiment of the present invention, the thickness of the seed layer ranges from about 10 nm to about 100 nm.

According to one embodiment of the present invention, the formation of the contact holes includes: forming contact holes within the second isolation layer above the semiconductor chip contact areas, wherein the contact holes reach at least to the top surface of the first isolation layer, however do not reach to the top surface of the semiconductor chip contact areas; filling the contact holes with filling material, depositing a seed layer on the top surface of the composite structure and the top surface of the filling material; removing the seed layer from the top surface of the filling material; forming a shielding layer on the seed layer; removing the filling material; and enlarging the contact holes such that they extend to the top surfaces of the semiconductor chip contacting areas.

According to one embodiment of the present invention, the thickness of the shielding layer ranges from about 10 μm to about 100 μm.

According to one embodiment of the present invention, the thickness of the shielding layer ranges from about 10 μm to about 100 μm.

According to one embodiment of the present invention, the shielding layer includes or consists of metallic material.

According to one embodiment of the present invention, the shielding layer includes or consists of NiFe.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A semiconductor device, comprising
a semiconductor chip comprising a magneto-resistive memory cell;
a surrounding structure, wherein the semiconductor chip is at least partly surrounded by the surrounding structure; and
a shielding layer disposed between the semiconductor chip and the surrounding structure, wherein the shielding layer is configured to shield the magneto-resistive memory cell from external magnetic fields.

2. The semiconductor device according to claim 1, wherein the shielding layer has a thickness that ranges from about 10 μm to about 100 μm.

3. The semiconductor device according to claim 1, wherein the shielding layer comprises a metallic material.

4. The semiconductor device according to claim 3, wherein the shielding layer comprises NiFe.

5. The semiconductor device according to claim 1, further comprising a first isolation layer and a second isolation layer between the shielding layer and the semiconductor chip, wherein the first isolation layer is different from the second isolation layer.

6. The semiconductor device according to claim 5, wherein the first isolation layer comprises SiO₂.

7. The semiconductor device according to claim 6, wherein the second isolation layer comprises SiN.

8. The semiconductor device according to claim 1, wherein a distance between the shielding layer and the magneto-resistive memory cell ranges from about 2 μm to about 40 μm.

9. The semiconductor device according to claim 1, wherein the surrounding structure comprises a molding mass.

10. A memory module comprising at least one semiconductor device, each semiconductor device comprising:
a semiconductor chip at least partly surrounded by a surrounding structure, the semiconductor chip comprising a magneto-resistive memory cell; and
a shielding layer disposed between the semiconductor chip and the surrounding structure, wherein the shielding layer is configured to shield the magneto-resistive memory cell from external magnetic fields.

11. The memory module according to claim 10, wherein the memory module is stackable.

12. A method of manufacturing a semiconductor device comprising a semiconductor chip and a magneto-resistive memory cell arranged within the semiconductor chip, the method comprising:
forming a composite structure comprising the semiconductor chip and a shielding layer that at least partly surrounds the semiconductor chip, wherein the shielding layer protects the magneto-resistive memory cell against an external magnetic field; and
at least partly surrounding the composite structure with a surrounding structure.

13. The method according to claim 12, wherein the semiconductor chip comprises semiconductor chip contacting areas located at or near to a top surface of the semiconductor chip.

14. The method according to claim 13, comprising:
forming contact holes within an isolation layer arranged on or above the semiconductor chip contacting areas, wherein the contact holes do not reach to top surfaces of the semiconductor chip contacting areas;
forming the shielding layer on or above a top surface of the isolation layer; and
extending the contact holes until they reach the top surfaces of the semiconductor chip contacting areas.

15. The method according to claim 14, further comprising contacting the semiconductor chip contacting areas via the contact holes before surrounding the composite structure with the surrounding structure.

16. The method according to claim 14, wherein the isolation layer comprises a first isolation layer that is provided on or above the top surface of the semiconductor chip, and a second isolation layer that is provided on or above the first isolation layer, wherein a material of the first isolation layer is different from a material of the second isolation layer.

17. The method according to claim 16, wherein, before forming the shielding layer, the contact holes are formed such that they reach to a top surface of the first isolation layer, wherein, after having formed the shielding layer, the contact holes are extended such that they reach to the top surfaces of the semiconductor chip contacting areas.

18. The method according to claim 17, wherein the first isolation layer comprises SiO₂.

19. The method according to claim 18, wherein the second isolation layer comprises SiN.

20. The method according to claim 14, further comprising forming a seed layer on or above the top surface of the isolation layer, wherein the shielding layer is formed on a top surface of the seed layer.

21. The method according to claim 20, wherein the seed layer comprises NiFe or Cu.

22. The method according to claim 20, wherein the seed layer has a thickness that ranges from about 10 nm to about 100 nm.

23. The method according to claim 16, wherein forming the contact holes comprises:
forming contact holes within the second isolation layer above the semiconductor chip contacting areas, wherein the contact holes reach at least to the top surface of the first isolation layer, however do not reach to the top surface of the semiconductor chip contacting areas;
filling the contact holes with filling material;
depositing a seed layer on a top surface of the composite structure and a top surface of the filling material;
removing the seed layer from the top surface of the filling material;
forming a shielding layer on the seed layer;
removing the filling material; and
extending the contact holes such that they extend to the top surfaces of the semiconductor chip contacting areas.

24. The method according to claim 12, wherein the shielding layer has a thickness that ranges from about 10 μm to about 100 μm.

25. The method according to claim 12, wherein the shielding layer comprises a metallic material.
